(19) United States
(12) Patent Application Publication
(10) Pub. No.: US 2008/0150108 A1
(43) Pub. Date: Jun. 26, 2008

(54) SEMICONDUCTOR PACKAGE AND METHOD FOR MANUFACTURING SAME

(75) Inventor: Miho Mochizuki, Saitama-ken (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/964,460

(22) Filed: Dec. 26, 2007

(30) Foreign Application Priority Data
Dec. 26, 2006 (JP) 2006-349772

(51) Int. Cl. H01L 23/495; H01L 21/60

(52) U.S. Cl. 257/677; 438/120; 257/E21.51; 257/E23.042

(57) ABSTRACT

A semiconductor package includes: a semiconductor chip and a plurality of frames. A plurality of electrodes are formed on a surface of the semiconductor chip. The plurality of frames are connected to the plurality of electrodes. The plurality of frames are formed by dividing one conductive plate by etching.

### CROSS-REFERENCE TO RELATED APPLICATIONS

This application is based upon and claims the benefit of priority from the prior Japanese Patent Application No. 2006-349772, filed on Dec. 26, 2006; the entire contents of which are incorporated herein by reference.

### BACKGROUND OF THE INVENTION

1. Field of the Invention

This invention relates to a semiconductor package and a method for manufacturing the same, and more particularly to a semiconductor package and a method for manufacturing the same where electrodes of a semiconductor chip are connected to a frame.

2. Background Art

A conventional problem in packaging a semiconductor chip is how to achieve downsizing while ensuring sufficient reliability. In a structure known as an example of conventional semiconductor packages, a semiconductor chip is fixed on a frame, and the electrodes of the semiconductor chip are connected to the frame through wires (see, e.g., JP 2006-332708A).

However, such a package needs, besides the connection region for connecting the electrode of the semiconductor chip to the wire, a connection region (second bonding area) for connecting the wire to the frame. Hence the package profile is unfortunately upsized in comparison with the size of the semiconductor chip. Furthermore, because the wire passes above the electrode formation surface of the semiconductor chip, a certain loop height is needed to prevent the wire from interfering with the semiconductor chip. Hence there are limitations on downsizing and profile reduction.

As another example of conventional semiconductor packages, a wafer level chip size package (WCSP) is known (see, e.g., JP-A 2006-066437(Kokai)). In the WCSP, a semiconductor chip is disposed facedown on a printed circuit board, and the electrodes of the semiconductor chip are connected to the electrodes of the printed circuit board through solder bumps. Thus, in the WCSP, the semiconductor chip is connected to the printed circuit board without using wires, hence allowing reduction in profile as compared with the package having wires. Furthermore, because the chip itself is used as an enclosure, the enclosure size is equal to the chip size, allowing downsizing.

However, in the WCSP, because the semiconductor chip is exposed, the chip may be cracked by external impact. Thus the WCSP has a problem of being vulnerable to mechanical stress and less reliable. Furthermore, the size of the enclosure depends on the area and arrangement pitch of its external electrodes. Hence, even if the circuit area is reduced by introducing downscaling techniques in circuit patterning, the chip area cannot be reduced accordingly. Thus it is impossible to reduce material cost by reducing the chip area.

As still another example of conventional semiconductor packages, a package based on flip chip bonding (FCB) is also known. In FCB, electrodes of the chip are connected to a frame by a plurality of gold (Au) bumps provided on the electrode formation surface of the semiconductor chip or the surface of the frame. This connection is formed by application of supersonic waves while applying a load to the chip.

However, in FCB, when the electrodes of the chip are connected to the frame, all the electrodes must be connected simultaneously. Hence the application of the load must be generally uniform for all the electrodes. However, in a semiconductor chip having a small number of electrodes such as a discrete product, uniform application of a load is difficult unless the number of electrodes is even and the electrodes are arranged symmetrically with respect to the chip center. Hence the number and arrangement of electrodes are restricted, and there is a problem of low design flexibility. Furthermore, because the bonding force of the connection using gold bumps is weak, the FCB-based package is less reliable.

### SUMMARY OF THE INVENTION

According to an aspect of the invention, there is provided a semiconductor package including: a semiconductor chip with a plurality of electrodes formed on a surface thereof; and a plurality of frames connected to the plurality of electrodes, the plurality of frames being formed by dividing one conductive plate by etching.

According to another aspect of the invention, there is provided a semiconductor package including: a semiconductor chip with a plurality of electrodes formed on a surface thereof and with a plurality of vias extending to the electrodes from backside formed; a conductive member buried inside the vias and connected to the electrode; and a plurality of frames disposed on the backside of the semiconductor chip and connected the plurality of electrodes through the conductive member.

According to another aspect of the invention, there is provided a method for manufacturing a semiconductor package, including: connecting one conductive plate to a plurality of electrodes formed on a surface of a semiconductor chip; and dividing the conductive plate by etching to form a plurality of frames connected to the plurality of electrodes.

### BRIEF DESCRIPTION OF THE DRAWINGS

FIGS. 1A to 1C are views illustrating a semiconductor package according to a first embodiment of the invention, where FIG. 1A is a top view, FIG. 1B is a bottom view, and FIG. 1C is a cross-sectional view taken along line A-A′ shown in FIGS. 1A and 1B;

FIG. 2 is a process cross-sectional view illustrating a method for manufacturing a semiconductor package according to this embodiment, where FIG. 2A is a top view, FIG. 2B is a bottom view, and FIG. 2C is a cross-sectional view taken along line A-A′ shown in FIGS. 2A and 2B;

FIG. 3 is a process cross-sectional view illustrating a method for manufacturing a semiconductor package according to this embodiment, where FIG. 3A is a top view, FIG. 3B is a bottom view, and FIG. 3C is a cross-sectional view taken along line A-A′ shown in FIGS. 3A and 3B;

FIG. 4 is a process cross-sectional view illustrating a method for manufacturing a semiconductor package according to this embodiment, where FIG. 4A is a top view, FIG. 4B is a bottom view, and FIG. 4C is a cross-sectional view taken along line A-A′ shown in FIGS. 4A and 4B;

FIG. 5 is a process cross-sectional view illustrating a method for manufacturing a semiconductor package according to this embodiment, where FIG. 5A is a top view, FIG. 5B is a bottom view, and FIG. 5C is a cross-sectional view taken along line A-A′ shown in FIGS. 5A and 5B;

FIG. 6 is a process cross-sectional view illustrating a method for manufacturing a semiconductor package according to this embodiment, where FIG. 6A is a top view, FIG. 6B is a bottom view, and FIG. 6C is a cross-sectional view taken along line A-A′ shown in FIGS. 6A and 6B;

FIG. 7 is a process cross-sectional view illustrating a method for manufacturing a semiconductor package according to this embodiment, where FIG. 7A is a top view, FIG. 7B is a bottom view, and FIG. 7C is a cross-sectional view taken along line A-A′ shown in FIGS. 7A and 7B;

FIG. 8 is a cross-sectional view illustrating a semiconductor package according to a second embodiment of the invention;

FIGS. 9A to 9C are views illustrating a semiconductor package according to a third embodiment of the invention, where FIG. 9A is a top view, FIG. 9B is a bottom view, and FIG. 9C is a cross-sectional view taken along line A-A′ shown in FIGS. 9A and 9B.

### DETAILED DESCRIPTION OF THE INVENTION

A semiconductor package and a method for manufacturing the same according to an embodiment of the invention will now be described with reference to the drawings.

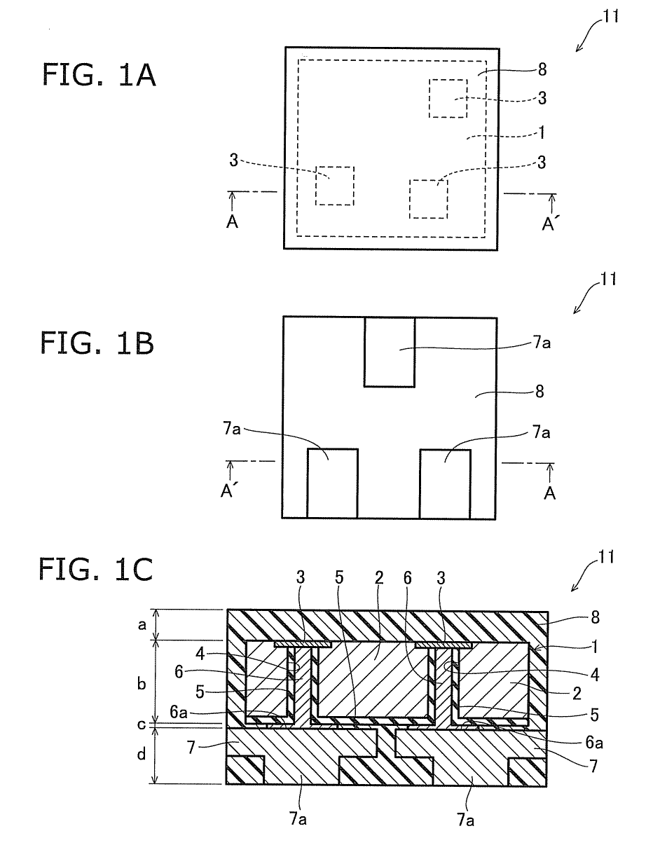

FIGS. 1A to 1C illustrate a semiconductor package according to this embodiment, where FIG. 1A is a top view, FIG. 1B is a bottom view, and FIG. 1C is a cross-sectional view taken along line A-A′ shown in FIGS. 1A and 1B.

As shown in FIGS. 1A to 1C, the semiconductor package 11 according to this embodiment includes a semiconductor chip 1. The semiconductor chip 1 is illustratively a discrete semiconductor chip, and the semiconductor package 11 is illustratively a package to be installed on an electronic apparatus such as a mobile phone. In the semiconductor chip 1, a plurality of electrodes 3 illustratively made of an impurity diffusion layer are formed in the surface of a substrate 2 illustratively made of single crystal silicon. The electrode 3 may also be formed from a metal layer or a silicide layer. Furthermore, a circuit (not shown) including transistors or other devices is also formed in the surface of the substrate 2.

A plurality of vias 4 are formed in the substrate 2 of the semiconductor chip 1 from backside to frontside. The via 4 reaches the electrode 3, but does not pass through the substrate 2. Each via 4 reaches one of the electrodes 3. In the example shown in FIG. 1, three electrodes 3 are formed, and also three vias 4 are formed. The arrangement of the electrodes 3 is not symmetric with respect to the center of the chip.

An insulating film 5 is formed on the inner side face of the via 4 and on the backside of the substrate 2. The insulating film 5 is illustratively a silicon oxide film. Furthermore, a conductive member 6 illustratively made of gold (Au) is buried inside the via 4, and the upper end of the conductive member 6 is connected to the electrode 3. On the other hand, the lower end of the conductive member 6 protrudes from the via 4. On the backside of the substrate 2, the lower end of the conductive member 6 spreads outside the directly underlying region of the via 4 and has an even surface. Thus the lower end of the conductive member 6 serves as a pad-shaped backside electrode 6a extracted onto the backside of the substrate 2. The insulating film 5 is interposed between the conductive member 6 and the inner surface of the via 4, and between the backside electrode 6a of the conductive member 6 and the backside of the substrate 2, thereby insulating the conductive member 6 from the substrate 2. Thus the electrode 3 is prevented from short-circuiting to members at other electric potentials such as interconnects exposed to the inner surface of the via 4 or the backside of the substrate 2.

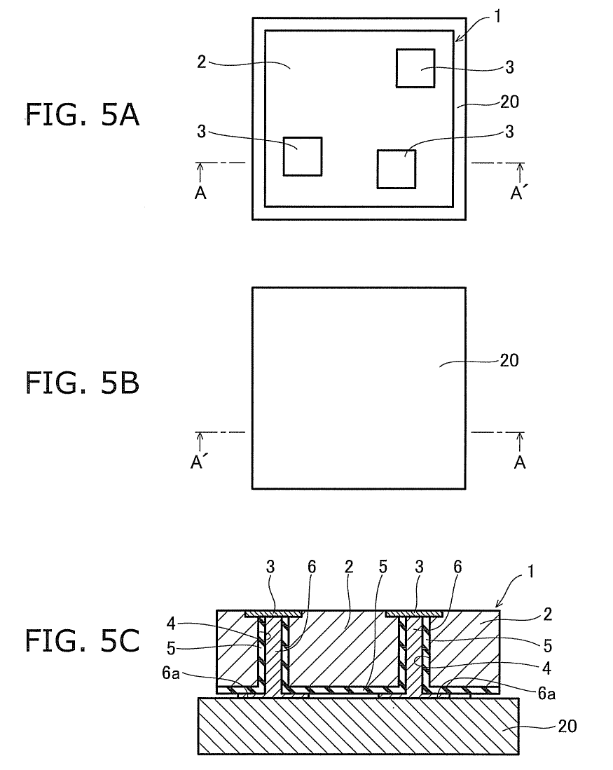

Furthermore, a plurality of frames 7 are provided on the backside of the semiconductor chip 1. In the example shown in FIG. 1, three frames 7 are provided. The frame 7 is illustratively made of copper (Cu) and forms an Au—Cu eutectic alloy with the backside electrode 6a of gold (Au), thereby being bonded to the backside electrode 6a. Thus each frame 7 is connected to the associated electrode 3 through the associated conductive member 6. One protrusion 7a, for example, is formed on the backside of each frame 7, that is, on the surface where the semiconductor chip 1 is not disposed. The plurality of frames 7 are formed by dividing one conductive plate 20 (see FIG. 5) by etching.

A mold resin 8 is provided so as to cover the semiconductor chip 1 and the frames 7. The semiconductor chip 1 is completely sealed with the mold resin 8. Each frame 7 is also largely sealed with the mold resin 8, but the top surface of the protrusion 7a of each frame 7 is exposed to the outer surface of the mold resin 8. The top surface of the protrusion 7a serves as an external electrode of the semiconductor package 11. That is, the external electrode of the semiconductor package 11 is an electrode of the LGA (land grid array) type. While a portion of the edge face of the frame 7 is also exposed to the outer surface of the mold resin 8 in the example shown in FIG. 1, this portion may be either exposed or not exposed.

In the following, an example set of dimensions for each portion of the semiconductor package 11 is presented. As shown in FIG. 1A, as viewed from above, the outline of the semiconductor package 11, or the outline of the resin mold 8, is a square, 1.1 mm long on a side. The outline of the semiconductor chip 1 is also a square, 1.0 mm long on a side. The resin mold 8 covering the side face of the semiconductor chip 1 has a thickness of 50 μm. That is, the dimensions of the semiconductor package 11 are limited to a 50-μm expansion on one side relative to the chip size. Furthermore, as shown in FIG. 1C, as viewed laterally, the length a, or the thickness of the resin mold 8 covering the surface of the semiconductor chip 1, is 50 μm; the length b, or the thickness of the semiconductor chip 1, is 100 μm; the length c, or the spacing between the semiconductor chip 1 and the frame 7, is 3 μm; and the length d, or the thickness of the frame 7, is 80 μm. Hence the total thickness of the semiconductor package 11 is illustratively 233 μm. It is noted that the outer dimensions of the semiconductor package 11 can be enlarged, if desired, by increasing the thickness of the resin mold 8 to more than 50 μm.

Next, a method for manufacturing a semiconductor package 11 according to this embodiment is described.

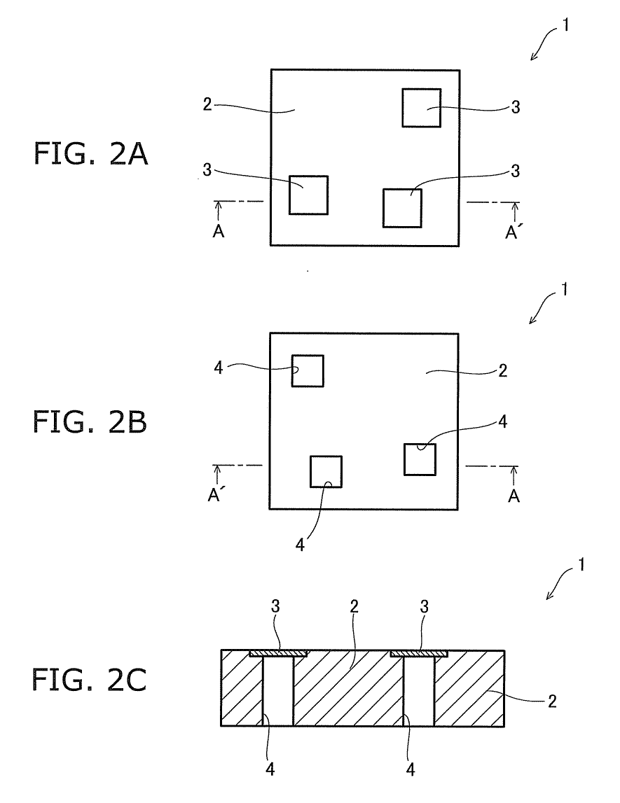

FIGS. 2 to 7 are process cross-sectional views illustrating the method for manufacturing a semiconductor package according to this embodiment. The figure labeled with the suffix A is a top view, the figure labeled with the suffix B is a bottom view, and the figure labeled with the suffix C is a cross-sectional view taken along line A-A′ shown in the associated figures labeled with the suffixes A and B.

First, as shown in FIGS. 2A to 2C, a semiconductor chip 1 is prepared. The semiconductor chip 1 includes a substrate 2 illustratively made of single crystal silicon, and a plurality of electrodes 3 illustratively made of an impurity diffusion layer are formed in the surface of the substrate 2. Furthermore, a circuit (not shown) including semiconductor devices is formed in the surface of the substrate 2.

In the semiconductor chip 1, vias 4 are formed from the directly underlying region of the electrodes 3 on the backside of the substrate 2 toward the frontside. Here, each via 4 is formed corresponding to one of the electrodes 3 so as to reach the electrode 3.

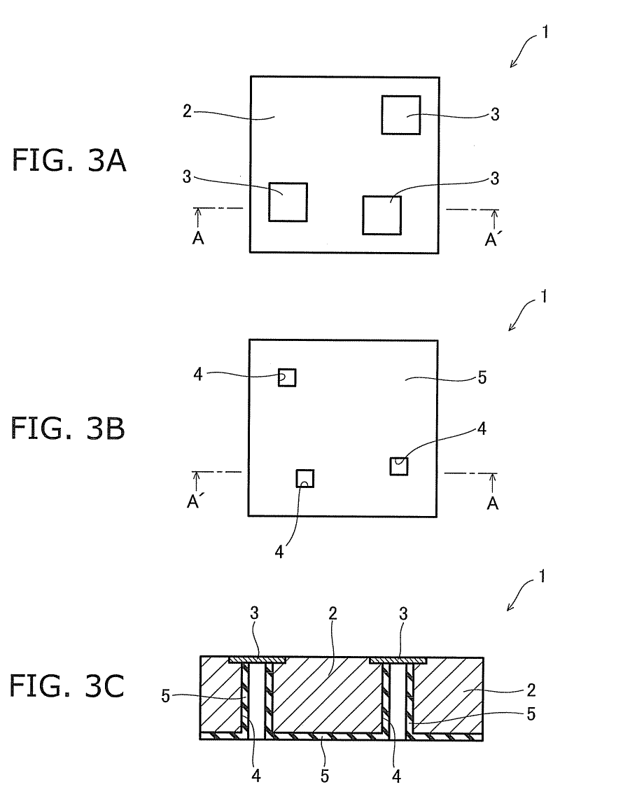

Next, as shown in FIGS. 3A to 3C, an insulating film 5 of silicon oxide is formed illustratively by thermal oxidation on the inner side face of the vias 4 and on the backside of the substrate 2.

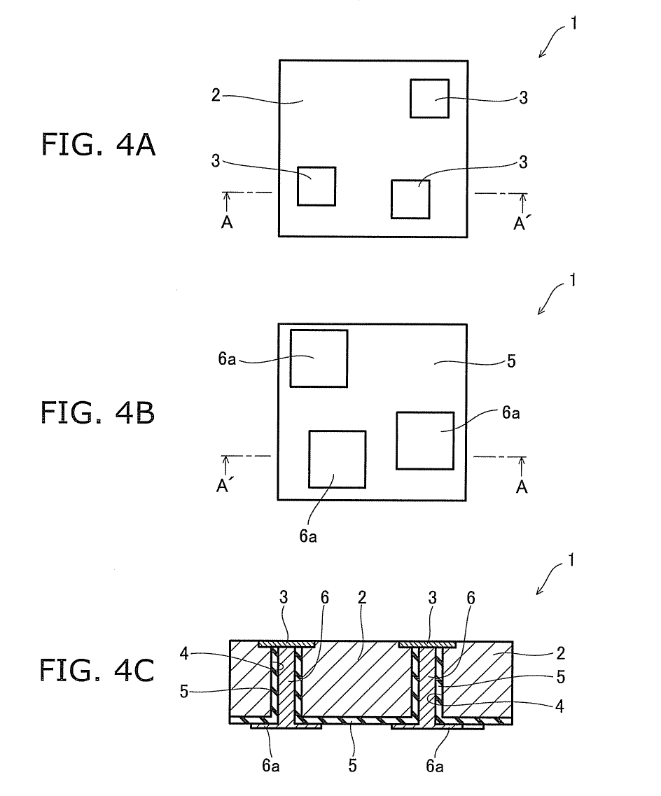

Next, as shown in FIGS. 4A to 4C, a conductive member 6 illustratively made of gold (Au) or a gold alloy is formed in the vias 4 and around the opening of the vias 4 on the backside of the substrate 2. Thus the upper end of the conductive member 6 is connected to the electrode 3, and the lower end is shaped like a pad to serve as a backside electrode 6a. Here, the conductive member 6 is insulated from the substrate 2 by the insulating film 5. Hence the conductive members 6 are extracted independently from each other onto the backside of the substrate 2 so that the potential of the electrode 3 does not short-circuit to or interfere with other electric potentials exposed to the inner surface of the via 4 and the backside of the substrate 2. It is noted that the backside electrode 6a may be formed simultaneously with the plug portion of the conductive member 6 buried in the via 4, or may be formed subsequently after the plug portion is formed. In the case of subsequent formation, it is also possible to form only the outermost layer of the backside electrode 6a from gold or a gold alloy by plating.

Next, as shown in FIGS. 5A to 5C, one conductive plate 20 is disposed on the backside of the semiconductor chip 1. The conductive plate 20 is a flat monolithic plate with its frontside and backside being even, and its outline is slightly larger than the outline of the semiconductor chip 1 as viewed from the semiconductor chip 1 side. The conductive plate 20 is illustratively made of copper (Cu). By application of supersonic waves with the conductive plate 20 pressed to the backside electrodes 6a, an Au—Cu eutectic alloy is formed between the conductive plate 20 of copper and the backside electrodes 6a of gold, thereby bonding the conductive plate 20 to all the backside electrodes 6a. That is, the conductive plate 20 is mechanically linked and electrically connected to the backside electrodes 6a. Consequently, the conductive plate 20 is connected to all the electrodes 3 through the conductive members 6.

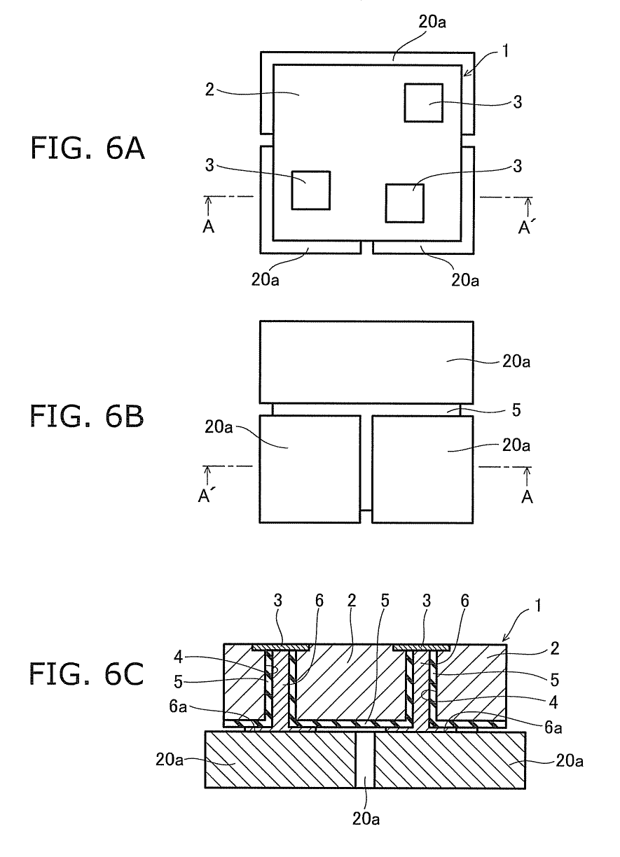

Next, as shown in FIGS. 6A to 6C, a mask pattern (not shown) is disposed on the backside of the conductive plate 20, that is, on the side where the semiconductor chip 1 is not disposed. The mask pattern is used as a mask to locally etch only the conductive plate 20. For example, when the conductive plate 20 is made of copper, wet etching is performed with nitric mixed acid. Thus the conductive plate 20 is divided for each electrode 3, and the remaining portions constitute a plurality of, e.g. three, portions 20a.

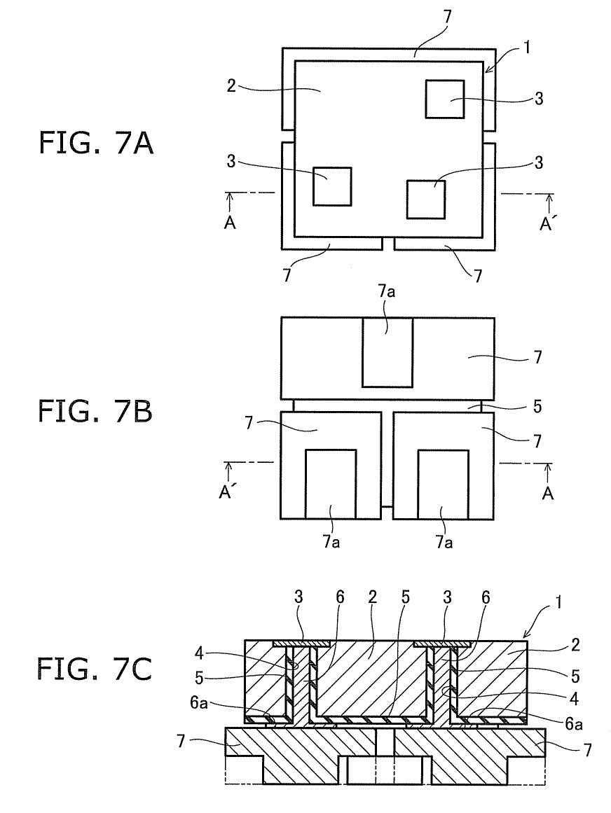

Next, as shown in FIGS. 7A to 7C, another mask pattern (not shown) is disposed on the backside of the portions 20a, and used as a mask to locally half-etch the portions 20a. Consequently, the half-etched region in each portion 20a is made thinner than the region not half-etched. The region not half-etched on the backside of the portion 20a constitutes a protrusion 7a. Thus a plurality of frames 7 with protrusions 7a on the backside are formed from one conductive plate 20.

Next, as shown in FIGS. 1A to 1C, a resin mold 8 is formed so as to expose the top surface of the protrusion 7a of the frames 7 and to cover the rest of the frames 7 and the overall semiconductor chip 1. Thus most of the frame 7 and the overall semiconductor chip 1 are sealed. Here, the edge face of the frame 7 that was the edge face of the conductive plate 20 before division may be exposed or not exposed to the outer surface of the resin mold 8. By the foregoing steps, a semiconductor package 11 is manufactured.

Next, the effect of this embodiment is described.

In this embodiment, after one conductive plate 20 is bonded to the backside electrodes 6a, the conductive plate 20 is divided by etching into a plurality of frames 7. Thus, when the conductive plate 20 is bonded to the backside electrodes 6a, the height of the bonding surface between the conductive plate 20 and the backside electrode 6a is not varied for each backside electrode 6a, and a load can be evenly applied to all the bonding surfaces. This results in a high connection stability between the backside electrode 6a and the frame 7, achieving high reliability. Furthermore, the conductive plate 20 can be stably connected to all the backside electrodes 6a even for an odd number of electrodes 3, which are asymmetric with respect to the center of the chip. Thus the electrode arrangement in the semiconductor chip 1 has high flexibility.

In this embodiment, vias 4 are formed in the substrate 2 of the semiconductor chip 1 from the backside, and electrodes 3 are extracted by the conductive members 6 to the backside of the substrate 2 and connected to the frames 7 disposed on the backside of the substrate 2. Thus, in the process of manufacturing a semiconductor package 11, the conductive plate 20 can be disposed on the backside of the semiconductor chip 1, that is, on the side opposite to the circuit formation surface. Hence the conductive plate 20 can be easily etched without damaging the circuit formed in the semiconductor chip 1.

In this embodiment, a protrusion 7a is formed in the frame 7, and the top surface of the protrusion 7a is exposed from the mold resin 8 to serve as an external electrode. Here, the position where the protrusion 7a is formed in the frame 7 can be defined irrespective of the bonding position of the frame 7 with the backside electrode 6a. Hence, irrespective of the arrangement of electrodes 3 in the semiconductor chip 1, the arrangement of the protrusions 7a serving as external electrodes can be freely determined in accordance with specifications or user requests. Thus a high flexibility is achieved in arrangement of the electrodes. Furthermore, if the circuit area can be reduced in the semiconductor chip 1, the chip area of the semiconductor chip 1 can be made smaller than the total area of the frames 7, hence allowing reduction in material cost.

In this embodiment, an Au—Cu eutectic alloy is formed when the backside electrode 6a is bonded to the frame 7. Thus the mechanical strength of this bonding portion can be increased, allowing enhancement in reliability.

In this embodiment, no wire is used for connecting the semiconductor chip 1 to the frame 7, allowing reduction in profile. This improves the chip mounting capability. Furthermore, because the semiconductor chip 1 is sealed with the resin mold 8, the semiconductor chip 1 can be protected from mechanical stress applied from outside. Hence the semiconductor package 11 has high reliability.

This embodiment can thus provide a semiconductor package that is more compact, low-profile, reliable, and flexible in arrangement of electrodes than conventional semiconductor packages described above. More specifically, as compared with conventional packages having wires, the semiconductor package 11 according to this embodiment does not need to include a connection region (second bonding area) for connecting a wire to a frame, allowing downsizing of the package. Furthermore, there is no need to thicken the resin mold for ensuring a sufficient loop height of the wire and preventing the wire from extending off the resin mold. Hence the profile of the package can be reduced. As compared with the conventional WCSP, the semiconductor chip can be protected by the resin mold, achieving high reliability. Furthermore, because use of the chip itself as an enclosure is avoided, the material cost can be reduced by decreasing the chip area if the circuit area can be decreased. Furthermore, as compared with the conventional FCB, the backside electrodes and the conductive plate can be pressurized more evenly and bonded together irrespective of the arrangement of the electrodes, hence achieving high flexibility in arrangement of electrodes and high connection reliability. Furthermore, the eutectic alloy formed at the bonding portion results in high bonding strength and high reliability.

In this embodiment, by using the conductive member 6 made of gold and the conductive plate 20 made of copper, an Au—Cu eutectic alloy is illustratively formed between the backside electrode 6a and the frame 7, and they are bonded together. However, the invention is not limited thereto. For example, the backside electrode 6a may be made of solder or silver (Ag) paste to bond the frame 7b to the backside electrode 6a with solder or silver paste. Also in this case, the frame 7 can be connected robustly and stably to the backside electrode 6a, allowing sufficient reliability.

In this embodiment, the number of electrodes 3 is illustratively three. However, the invention is not limited thereto, but the number may be two, or four or more. In this case, the number of vias 4 and frames 7 is also two, or four or more.

Next, a second embodiment of the invention is described.

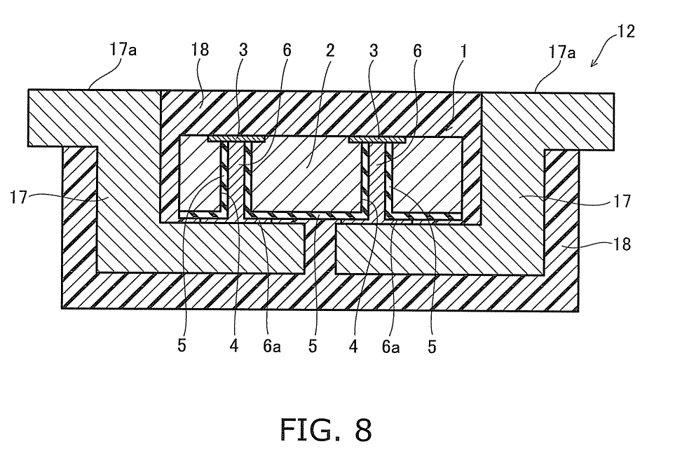

FIG. 8 is a cross-sectional view illustrating a semiconductor package according to this embodiment.

As shown in FIG. 8, the semiconductor package 12 according to this embodiment is different in the configuration of the frame and the resin mold from the semiconductor package 11 (see FIG. 1) according to the first embodiment described above.

In the semiconductor package 12, no protrusion is formed in the frame 17. Each frame 17 has a generally Z-shaped configuration. More specifically, the frame 17 is once extracted from the junction with the backside electrode 6a to the lateral side of the semiconductor chip 1. The frame 17 is then bent at a generally right angle, extends upward, or in the direction from the backside to the frontside of the substrate 2, passes on the lateral side of the semiconductor chip 1, and extends higher than the semiconductor chip 1. The frame 17 is then bent again at a generally right angle and extracted away from the semiconductor chip 1.

The resin mold 18 seals the overall semiconductor chip 1 and most of the frames 17. The frame 17 is exposed from the resin mold 18 only at its upper surface 17a located higher than the semiconductor chip 1 and at its end portion on the far side from the semiconductor chip 1. In the semiconductor package 12, the upper surface 17a of the frame 17 serves as an external electrode. The configuration in this embodiment other than the foregoing is the same as that in the first embodiment described above.

Such a frame 17 can be formed illustratively by the following procedure. One flat conductive plate with the outline being considerably larger than the outline of the semiconductor chip 1 is prepared as the conductive plate 20 (see FIG. 5) and bonded to the backside electrodes 6a. Next, the conductive plate is divided by etching into a plurality of lead-shaped portions largely extracted on the backside of the semiconductor chip 1 from the junction with the backside electrodes 6a to the lateral side of the semiconductor chip 1. By bending work, the lead-shaped portion is bent at two locations into a Z-shaped configuration to serve as a frame 17. The manufacturing method in this embodiment other than the foregoing is the same as that in the first embodiment described above.

In this embodiment, after the semiconductor package 12 is mounted on a mounting substrate (not shown), a thermal stress caused by the difference between the thermal expansion coefficient of the mounting substrate and the thermal expansion coefficient of the semiconductor package 12 may be applied to the external electrode (upper surface 17a) of the semiconductor package 12. However, this thermal stress can be alleviated by the deformation of the bending portion of the frame 17 and prevented from propagating to the junction between the frame 17 and the semiconductor chip 1. Thus the connection reliability of the semiconductor package 12 can be further enhanced. The operation and effect in this embodiment other than the foregoing are the same as those in the first embodiment described above.

Next, a third embodiment of the invention is described.

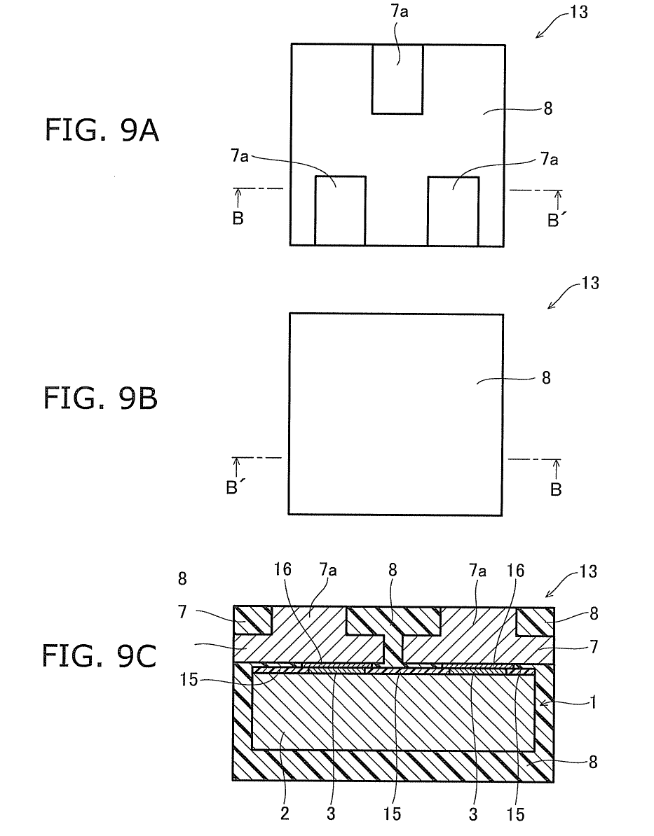

FIGS. 9A to 9C illustrate a semiconductor package according to this embodiment, where FIG. 9A is a top view, FIG. 9B is a bottom view, and FIG. 9C is a cross-sectional view taken along line B-B′ shown in FIGS. 9A and 9B.

As shown in FIGS. 9A to 9C, the semiconductor package 13 according to this embodiment is different from the semiconductor package 11 (see FIG. 1) according to the first embodiment described above in that the frame 7 is disposed on the frontside of the semiconductor chip 1, that is, on the circuit formation surface side. More specifically, the semiconductor package 13 has no vias in the substrate 2. An insulating layer 15 illustratively made of polyimide is formed on the region of the surface of the substrate 2 outside the electrodes 3. A surface electrode 16 made of a conductive material such as gold, solder, or silver paste is formed on the electrode 3. The frame 7 is connected to the electrode 3 through the surface electrode 16 and has a protrusion 7a protruding to the frontside. The top surface of the protrusion 7a is exposed from the mold resin 8 to serve as an external electrode of the semiconductor package 13. The configuration in this embodiment other than the foregoing is the same as that in the first embodiment described above.

Next, a method for manufacturing a semiconductor package according to this embodiment is described.

First, an insulating layer 15 illustratively made of polyimide is formed on the region of the surface of the substrate 2 of the semiconductor chip 1 outside the electrodes 3, and the surface of the insulating layer 15 is planarized. Next, a surface electrode 16 is formed from a conductive material such as gold, solder, or silver paste on the electrode 3 of the semiconductor chip 1. Here, the insulating layer 15 formed on the substrate 2 can serve to prevent the surface electrodes 16 from short-circuiting to or interfering with conductive members (not shown) such as devices and interconnects formed on the surface of the substrate 2.

Next, one flat conductive plate 20 (see FIG. 5) is disposed on the surface of the semiconductor chip 1 and bonded to the electrodes 3 through the surface electrodes 16. Next, the conductive plate 20 is selectively removed by etching and divided into a plurality of portions. Here, for example, when the conductive plate 20 is made of copper, wet etching is performed with nitric mixed acid. Subsequently, the divided portions of the conductive plate 20 are half-etched to form frames 7 having protrusions 7a. The manufacturing method in this embodiment other than the foregoing is the same as that in the first embodiment described above.

According to this embodiment, the frames are connected to the electrodes of the semiconductor chip without forming vias in the substrate and burying conductive members therein. Thus a semiconductor package can be manufactured more conveniently and cost-effectively than in the first embodiment described above. The operation and effect in this embodiment other than the foregoing are the same as those in the first embodiment described above.

The features of the invention have been described with reference to the embodiments. However, the invention is not limited to these embodiments. For example, in any of the above embodiments, the design can be changed, the process can be varied, and the components or steps can be added or deleted as appropriate by those skilled in the art, and such modifications are encompassed within the scope of the invention as long as they include the features of the invention.

1. A semiconductor package comprising:
a semiconductor chip with a plurality of electrodes formed on a surface thereof; and
a plurality of frames connected to the plurality of electrodes,
the plurality of frames being formed by dividing one conductive plate by etching.

2. The semiconductor package according to claim 1, further comprising:
a mold resin configured to seal the semiconductor chip and the frames,
a protrusion being formed on a surface of each of the frames, the surface being on a side where the semiconductor chip is not disposed, and
the protrusion being exposed to an outer surface of the mold resin.

3. The semiconductor package according to claim 1, wherein
a plurality of vias extending to the electrodes from backside are formed in a substrate of the semiconductor chip,
a conductive member connected to the electrode is buried inside the vias, and
the frames are disposed on the backside of the substrate and connected to the electrodes through the conductive member.

4. The semiconductor package according to claim 3, further comprising a backside electrode provided on the backside of the substrate and disposed between the conductive member buried in the vias and the frame.

5. The semiconductor package according to claim 4, wherein the backside electrode is formed based on that a lower end of the conductive member protrudes from the vias and spreads outside a directly underlying region of the vias on the backside of the substrate.

6. The semiconductor package according to claim 4, wherein the backside electrode is made of gold, the frame is made of copper, and an Au—Cu eutectic alloy is formed between the backside electrode and the frame.

7. The semiconductor package according to claim 4, wherein the backside electrode is made of one of solder and silver (Ag) paste.

8. The semiconductor package according to claim 1, wherein the electrode is made of an impurity diffusion layer formed in a substrate of the semiconductor chip.

9. The semiconductor package according to claim 1, wherein the frame is bent.

10. The semiconductor package according to claim 1, wherein a circuit is formed in a surface of a substrate of the semiconductor chip.

11. The semiconductor package according to claim 1, wherein the frame is disposed on a frontside of the semiconductor chip.

12. A semiconductor package comprising:
a semiconductor chip with a plurality of electrodes formed on a surface thereof and with a plurality of vias extending to the electrodes from backside formed;
a conductive member buried inside the vias and connected to the electrode; and
a plurality of frames disposed on the backside of the semiconductor chip and connected the plurality of electrodes through the conductive member.

13. The semiconductor package according to claim 12, wherein the plurality of frames are formed by dividing one conductive plate by etching.

14. The semiconductor package according to claim 12, further comprising a mold resin configured to seal the semiconductor chip and the frames,
a protrusion being formed on a surface of each of the frames, the surface being on a side where the semiconductor chip is not disposed, and
the protrusion being exposed to an outer surface of the mold resin.

15. A method for manufacturing a semiconductor package, comprising:
connecting one conductive plate to a plurality of electrodes formed on a surface of a semiconductor chip; and
dividing the conductive plate by etching to form a plurality of frames connected to the plurality of electrodes.

16. The method for manufacturing a semiconductor package according to claim 15, further comprising:
half-etching the frame to form a protrusion; and
sealing the semiconductor chip and the frames with a mold resin so as to expose the protrusion.

17. The method for manufacturing a semiconductor package according to claim 15, further comprising:
forming a plurality of vias in a substrate of the semiconductor chip from backside so that the vias reach the electrodes; and
burying a conductive member inside the via so that the conductive member is connected to the electrode,
wherein the connecting one conductive plate includes disposing the conductive plate on the backside of the substrate and connecting the conductive plate to the electrodes through the conductive member.

18. The method for manufacturing a semiconductor package according to claim 17, wherein the burying the conductive member includes forming a backside electrode connected to the conductive member on the backside of the substrate.

19. The method for manufacturing a semiconductor package according to claim 18, wherein
the backside electrode is made of gold and the conductive plate is made of copper, and
the bonding the conductive plate includes applying supersonic waves while pressing the conductive plate to the backside electrode.

20. The method for manufacturing a semiconductor package according to claim 18, further comprising bending a portion of the frame, which is extracted to the lateral side of the semiconductor chip.
